(19) United States
(12) Patent Application Publication
(10) Pub. No.: US 2024/0421047 A1
(43) Pub. Date: Dec. 19, 2024

(54) SEMICONDUCTOR MODULE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Hiroshi ISHINO, Nisshin-shi (JP)

(21) Appl. No.: 18/630,326

(22) Filed: Apr. 9, 2024

(30) Foreign Application Priority Data
Jun. 15, 2023 (JP) 2023-098595

(51) Int. Cl. H01L 23/495; H01L 23/31

(52) U.S. Cl. CPC H01L 23/49558; H01L 23/3107; H01L 23/49575

(57) ABSTRACT

A semiconductor module includes a first module and a second module. The first module and the second module are connected to each other by connecting terminals thereof. The first module and the second module are disposed to face each other in a thickness direction of the first module, and a direction of a current path in the first module is opposite to a direction of a current path in the second module.

### CROSS REFERENCE TO RELATED APPLICATION

The present application claims the benefit of priority from Japanese Patent Application No. 2023-098595 filed on Jun. 15, 2023. The entire disclosures of the above application are incorporated herein by reference.

### TECHNICAL FIELD

The present disclosure relates to a semiconductor module.

### BACKGROUND

For example, a three-level inverter device having a first power module, a second power module, and a third power module has been known. The first power module has a first power transistor in an upper arm, and a first diode in a lower arm. The second power module has a second power transistor in an upper arm, and a third power transistor in a lower arm. The third power module has a second diode in an upper arm, and a fourth power transistor in a lower arm.

### SUMMARY

The present disclosure describes a semiconductor module that includes a first module and a second module and is capable of suppressing an increase in inductance. According to an aspect, the first module and the second module are connected to each other by connecting terminals thereof. The first module and the second module are disposed to face each other in a thickness direction of the first module, and a direction of a current path in the first module is opposite to a direction of a current path in the second module.

### BRIEF DESCRIPTION OF DRAWINGS

Objects, features and advantages of the present disclosure will become more apparent from the following detailed description made with reference to the accompanying drawings, in which like parts are designated by like reference numerals and in which:

FIG. 1 is a circuit diagram of a semiconductor module according to a first embodiment;

FIG. 2 is a plan view of a first module of the semiconductor module on a drain side;

FIG. 3 is a plan view of the first module on a source side;

FIG. 4 is a cross-sectional view of the semiconductor module taken along a line IV-IV in FIGS. 2 and 3;

FIG. 5 is a cross-sectional view of the semiconductor module taken along a line V-V in FIGS. 2 and 3;

FIG. 6 is a cross-sectional view of the semiconductor module taken along a line VI-VI in FIG. 3;

FIG. 7 is a cross-sectional view of the semiconductor module taken along a line VII-VII in FIG. 3;

FIG. 8 is a cross-sectional view of the semiconductor module taken along a line VIII-VIII in FIGS. 2 and 3;

FIG. 9 is a plan view of a second module of the semiconductor module on a drain side;

FIG. 10 is a plan view of the second module on a source side;

FIG. 11 is a perspective view of an extension part and a capacitor of the semiconductor module;

FIG. 12 is a cross-sectional view of the extension part and the capacitor;

FIG. 13 is a circuit diagram showing a first commutation path of the semiconductor module;

FIG. 14 is a circuit diagram showing a second commutation path of the semiconductor module;

FIG. 15 is a circuit diagram showing a third commutation path of the semiconductor module;

FIG. 16 is a circuit diagram showing a fourth commutation path of the semiconductor module;

FIG. 17 is a diagram showing the first commutation path and the third commutation path when viewed on the drain side of the first module;

FIG. 18 is a diagram showing the first commutation path and the third commutation path when viewed on the drain side of the second module;

FIG. 19 is a diagram showing the second commutation path and the fourth commutation path when viewed on the drain side of the first module;

FIG. 20 is a diagram showing the second commutation path and the fourth commutation path when viewed on the drain side of the second module;

FIG. 21 is a plan view of a first module of a semiconductor module on a drain side, according to a second embodiment;

FIG. 22 is a plan view of the first module on a source side;

FIG. 23 is a plan view of a second module of the semiconductor module on a drain side; and

FIG. 24 is a plan view of the second module on a source side.

### DETAILED DESCRIPTION

To begin with, a relevant technology will be described only for understanding

the embodiments of the present disclosure.

For example, in a three-level inverter device having a first power module, a second power module, and a third power module, the first power module has a first power transistor in an upper arm, and a first diode in a lower arm. The second power module has a second power transistor in an upper arm, and a third power transistor in a lower arm. The third power module has a second diode in an upper arm, and a fourth power transistor in a lower arm.

In such a three-level inverter device, it is necessary to connect between the first power module and the second power module through wirings, and between the second power module and the third power module through wirings. These wirings increase the inductance of the three-level inverter device.

The present disclosure provides a semiconductor module that includes a first module and a second module and is capable of suppressing an increase in inductance.

According to an aspect of the present disclosure, a semiconductor module includes a first module and a second module. The first module includes a first terminal, a first element, a second element, a second terminal, and a third terminal. The first terminal is extended in a first direction. The first element includes: a first electrode connected to the first terminal; a second electrode; a first gate electrode that causes a current to flow between the first electrode and the second electrode in response to a voltage application; and a first diode connected to the first electrode and the second electrode. The second element includes: a third electrode connected to the second electrode; a fourth electrode; a second gate electrode that causes a current to flow between the third electrode and the fourth electrode in response to a voltage application; and a second diode connected to the third electrode and the fourth electrode. The second terminal is connected to the third electrode, extended in the first direction, and is to be connected to a load. The third terminal is connected to the fourth electrode and extended in the first direction. The second module includes a fourth terminal, a third element, a fourth element, a fifth terminal, and a sixth terminal. The fourth terminal is extended in the first direction and is connected to the second terminal so as to connect the first module and the second module to each other. The third element includes: a fifth electrode connected to the fourth terminal; a sixth terminal; a third gate electrode that causes a current to flow between the fifth electrode and the sixth electrode in response to a voltage application; and a third diode connected to the fifth electrode and the sixth electrode. The fourth element includes: a seventh electrode; an eighth electrode connected to the sixth electrode; a fourth gate that causes a current to flow between the seventh electrode and the eighth electrode in response to a voltage application; and a fourth diode connected to the seventh electrode and the eighth electrode. The fifth terminal is connected to the seventh electrode and extended in the first direction. The sixth terminal is connected to the seventh electrode and extended in the first direction. The first module is disposed to face the second module in a thickness direction of the first module. Further, the first module and the second module are configured so that a direction of a current path in the first module is opposite to a direction of a current path in the second module.

As a result, there is a place where the directions of magnetic fields caused by the currents flowing through the first module and the second module are different from each other. Therefore, the first module and the second module can cancel the magnetic fields each other. As such, an increase in inductance in the first module and the second module is suppressed. Further, an increase in inductance of the semiconductor module is suppressed.

Hereinafter, embodiments of the present disclosure will be described with reference to the drawings. In the following embodiments, the same or equivalent portions are denoted by the same reference numerals, and the description thereof will not be repeated.

### First Embodiment

In a semiconductor module of the present embodiment, an increase in inductance of the semiconductor module is suppressed. The semiconductor module is used, for example, in a bidirectional switch type three-level inverter.

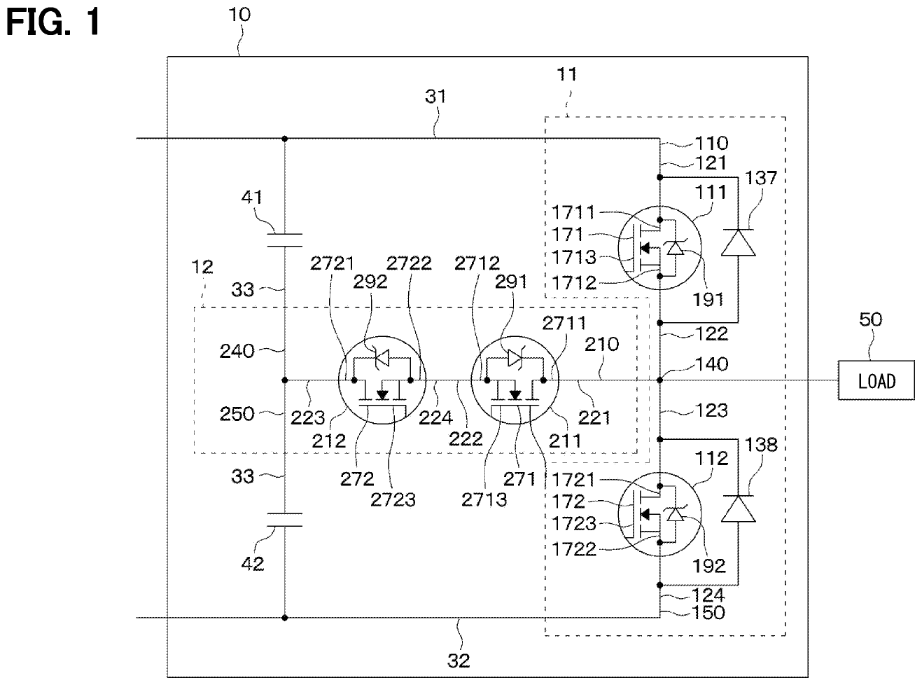

Specifically, as shown in FIGS. 1 to 12, the semiconductor module 10 includes a first module 11, a second module 12, a first extension part 31, a second extension part 32, a third extension part 33, a first capacitor 41 and a second capacitor 42.

As shown in FIGS. 1 to 8, the first module 11 has a P terminal 110, a first semiconductor element 111, a first lead frame 121, a second lead frame 122, and a first lead terminal 131. The first module 11 further includes a second semiconductor element 112, a third lead frame 123, a fourth lead frame 124, a second lead terminal 132, a first freewheeling diode 137, a second freewheeling diode 138, an O1 terminal 140, an N terminal 150 and a first sealing part 160.

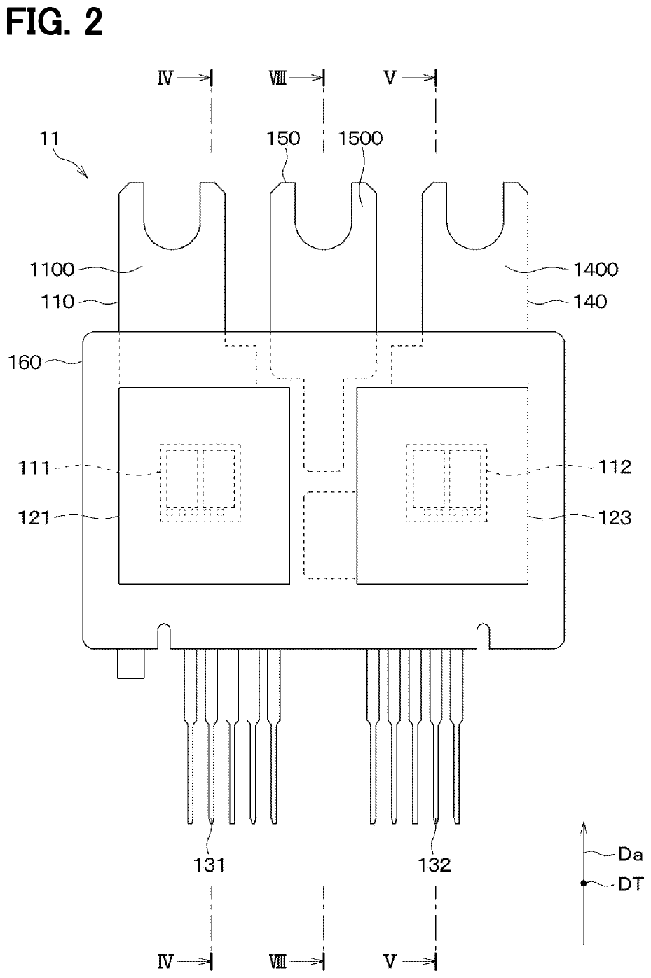

The P terminal 110 corresponds to a first terminal, and is made of metal. The P terminal 110 has a plate shape extending in one direction Da, as shown in FIGS. 2 to 4. The one direction Da corresponds to a first direction.

The first semiconductor element 111 corresponds to a first element. The first semiconductor element 111 includes a first transistor 171, a first bonding wire 181, and a first diode 191, as shown in FIGS. 1 to 4.

The first transistor 171 is, for example, a metal oxide semiconductor field effect transistor (MOSFET) using silicon (Si) or silicon carbide (SiC).

Further, the first transistor 171 has a first drain electrode 1711, a first source electrode 1712, and a first gate electrode 1713, as shown in FIG. 1.

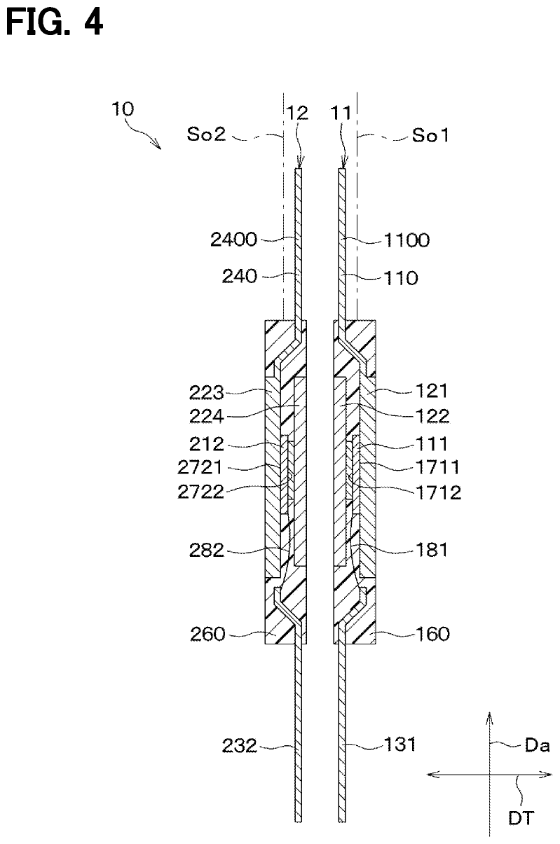

The first drain electrode 1711 corresponds to a first electrode. As shown in FIG. 4, the first drain electrode 1711 is connected to the first lead frame 121 via solder or the like. The first lead frame 121 is connected to the P terminal 110 via solder or the like. Therefore, the first drain electrode 1711 is connected to the P terminal 110 via the first lead frame 121 and the like. In addition to the function of a connection component, the first lead frame 121 has a function of a heat spreader.

The first source electrode 1712 corresponds to a second electrode. The first source electrode 1712 is connected to the second lead frame 122 via solder, a copper spacer, or the like. In addition to the function of a connection component, the second lead frame 122 has a function of a heat spreader.

The first gate electrode 1713 is connected to the first lead terminal 131 via a pad, the first bonding wire 181, and the like. The first lead terminal 131 is connected to a drive circuit (not shown). The first gate electrode 1713 causes a current to flow between the first drain electrode 1711 and the first source electrode 1712 in accordance with the voltage applied to the first gate electrode 1713 from the drive circuit.

Returning to FIG. 1, the first diode 191 is, for example, a Zener diode. A cathode of the first diode 191 is connected to the first drain electrode 1711 and the first lead frame 121. An anode of the first diode 191 is connected to the first source electrode 1712 and the second lead frame 122. Thus, the first diode 191 is connected in parallel with the first transistor 171.

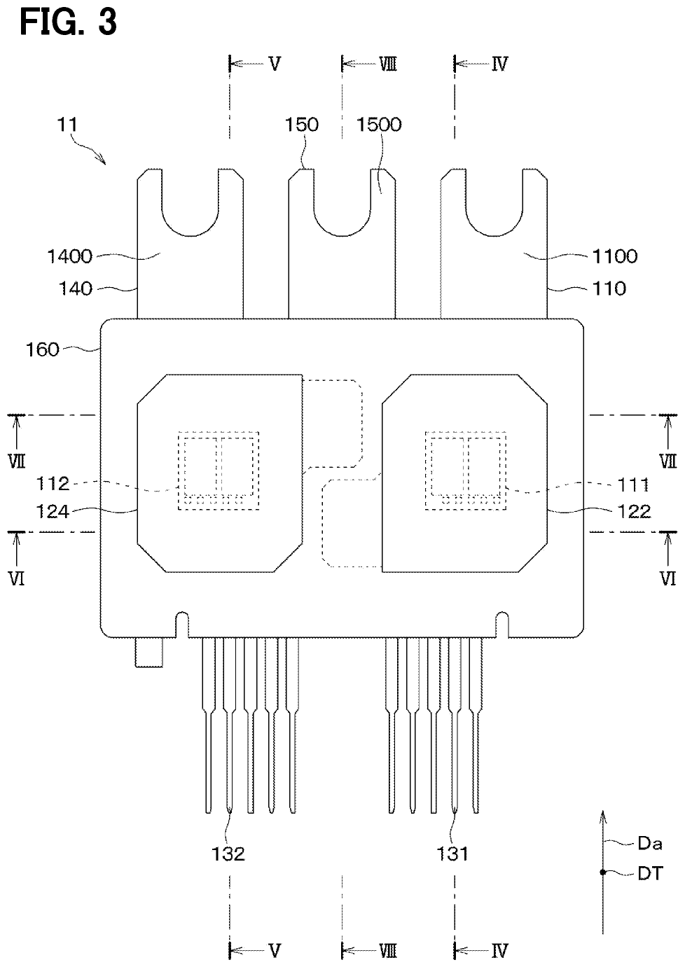

As shown in FIGS. 2 and 3, the second semiconductor element 112 is lined up with the first semiconductor element 111 in a direction that is perpendicular to the one direction Da and a thickness direction DT of the first semiconductor element 111. The second semiconductor element 112 corresponds to a second element. The second semiconductor element 112 includes a second transistor 172, a second bonding wire 182, and a second diode 192. Note that the thickness direction DT of the first semiconductor element 111 corresponds to the thickness direction of the first module 11.

The second transistor 172 is, for example, a MOSFET using Si or SiC. As shown in FIG. 1, the second transistor 172 has a second drain electrode 1721, a second source electrode 1722, and a second gate electrode 1723.

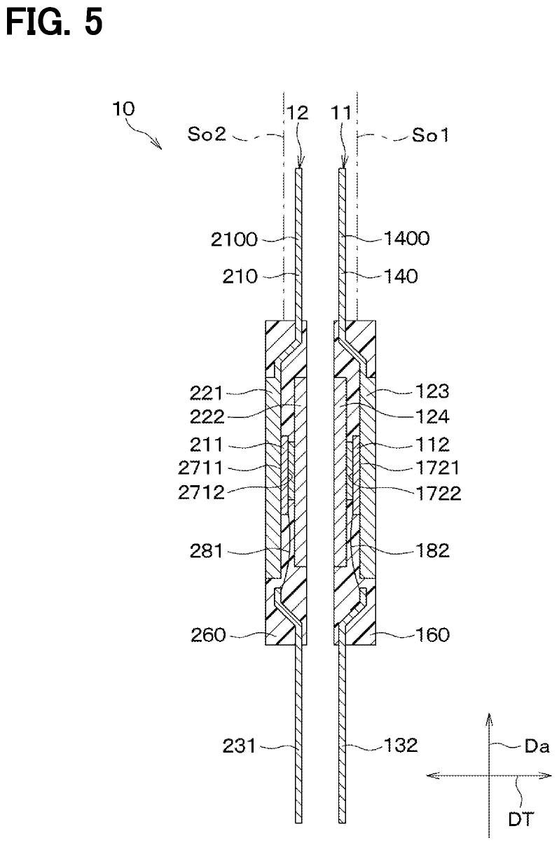

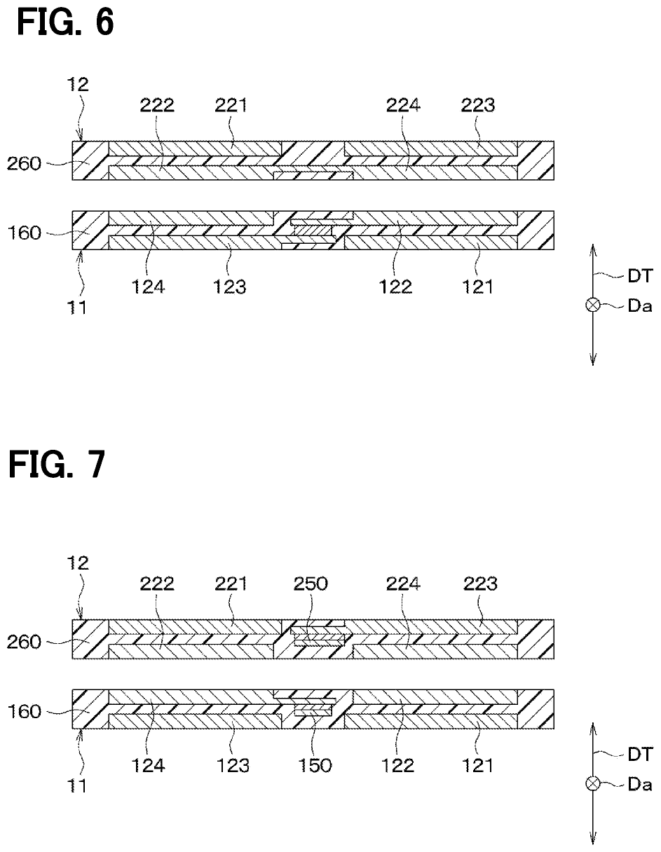

The second drain electrode 1721 corresponds to a third electrode. As shown in FIG. 5, the second drain electrode 1721 is connected to the third lead frame 123 via a solder or the like. As shown in FIG. 6, the third lead frame 123 is connected to the second lead frame 122 via a wiring layer, solder, a copper spacer, and the like. Therefore, the second drain electrode 1721 is connected to the first source electrode 1712 via the third lead frame 123, the second lead frame 122, and the like. The third lead frame 123 has the function of a heat spreader, in addition to the function of a connection component.

The second source electrode 1722 corresponds to a fourth electrode. As shown in FIG. 5, the second source electrode 1722 is connected to the fourth lead frame 124 via a solder, a copper spacer, or the like. In addition to the function of a connection component, the fourth lead frame 124 has a function of a heat spreader.

The second gate electrode 1723 is connected to the second lead terminal 132 via a pad, the second bonding wire 182, and the like. The second lead terminal 132 is connected to the drive circuit. The second gate electrode 1723 causes a current to flow between the second drain electrode 1721 and the second source electrode 1722 in accordance with the voltage applied to the second gate electrode 1723 from the drive circuit.

Returning to FIG. 1, the second diode 192 is, for example, a Zener diode. A cathode of the second diode 192 is connected to the second drain electrode 1721 and the third lead frame 123. An anode of the second diode 192 is connected to the second source electrode 1722 and the fourth lead frame 124. Thus, the second diode 192 is connected in parallel with the second transistor 172.

The first freewheeling diode 137 is connected in parallel with the first semiconductor element 111. The second freewheeling diode 138 is connected in parallel with the second semiconductor element 112.

The O1 terminal 140 corresponds to a second terminal. As shown in FIG. 5, the O1 terminal 140 is connected to the third lead frame 123 via a solder or the like. Since the third lead frame 123 is connected to the second drain electrode 1721, the O1 terminal 140 is connected to the second drain electrode 1721 via the third lead frame 123 and the like. Further, the third lead frame 123 is connected to the second lead frame 122, and the second lead frame 122 is connected to the first source electrode 1712. Therefore, the O1 terminal 140 is connected to the first source electrode 1712 via the third lead frame 123 and the second lead frame 122. The O1 terminal 140 is made of a metal and has a plate shape extending in the one direction Da. As shown in

FIG. 1, the O1 terminal 140 is connected to a load 50. The load 50 is, for example, an LC filter or a motor.

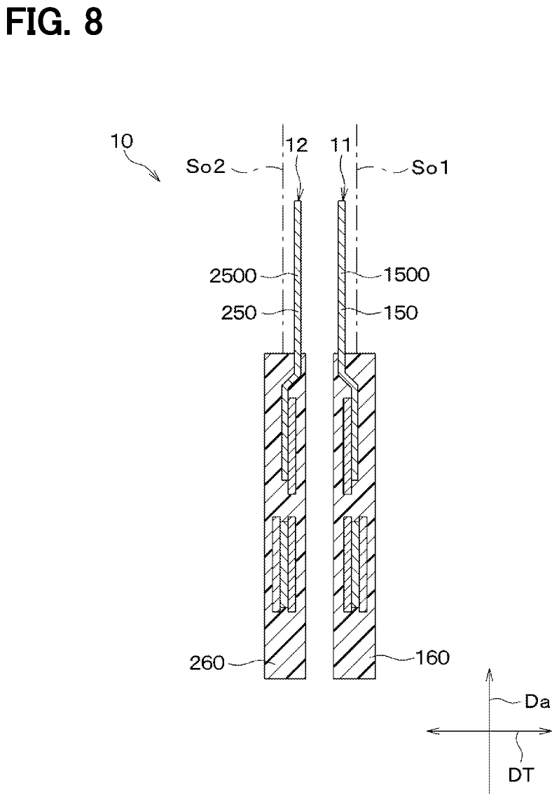

The N terminal 150 corresponds to a third terminal. As shown in FIG. 7, the N terminal 150 is connected to the fourth lead frame 124 via a wiring layer, a solder, a copper spacer, and the like. Since the fourth lead frame 124 is connected to the second source electrode 1722, the N terminal 150 is connected to the second source electrode 1722 via the fourth lead frame 124. As shown in FIG. 8, the N terminal 150 is made of a metal and has a plate shape extending in the one direction Da. In addition, as shown in FIGS. 2 and 3, the N terminal 150 is arranged between the P terminal 110 and the O1 terminal 140 in the direction perpendicular to the one direction Da and the thickness direction DT, and is spaced apart from the P terminal 110 and the O1 terminal 140.

The first sealing part 160 is made of a resin or the like. The first sealing part 160 covers the first semiconductor element 111, the second semiconductor element 112, the first freewheeling diode 137, and the second freewheeling diode 138. The first sealing part 160 covers the first lead frame 121 and the second lead frame 122 so that the first lead frame 121 and the second lead frame 122 are partly exposed from the first sealing part 160. The first sealing part 160 covers the third lead frame 123 and the fourth lead frame 124 so that the third lead frame 123 and the fourth lead frame 124 are partly exposed from the first sealing part 160. The first sealing part 160 covers a part of the first lead terminal 131 so that the first lead terminal 131 protrudes from the first sealing part 160. The first sealing part 160 covers a part of the second lead terminal 132 so that the second lead terminal 132 protrudes from the first sealing part 160. The first sealing part 160 covers a part of the P terminal 110 so that the P terminal 110 protrudes from the first sealing part 160. The first sealing part 160 covers a part of the O1 terminal 140 so that the O1 terminal 140 protrudes from the first sealing part 160. The first sealing part 160 covers a part of the N terminal 150 so that the N terminal 150 protrudes from the first sealing part 160.

Therefore, as shown in FIGS. 2 to 5 and 8, the P terminal 110 has a first protrusion 1100 that protrudes from the first sealing part 160. The O1 terminal 140 has a second protrusion 1400 protruding from the first sealing part 160. The N terminal 150 has a third protrusion 1500 that protrudes from the first sealing part 160.

As shown in FIGS. 4 to 8, the second module 12 faces the first module 11 in the thickness direction DT. Further, the second module 12 includes an O2 terminal 210, a third semiconductor element 211, a fifth lead frame 221, a sixth lead frame 222, and a third lead terminal 231. Further, the second module 12 includes a fourth semiconductor element 212, a seventh lead frame 223, an eighth lead frame 224, a fourth lead terminal 232, an N1 terminal 240, an N2 terminal 250, and a second sealing part 260.

The O2 terminal 210 corresponds to a fourth terminal, and is connected to the O1 terminal 140 via a bolt, a nut or the like (not shown). Thereby, the first module 11 and the second module 12 are connected to each other. As shown in FIG. 5, the O2 terminal 210 is made of a metal and has a plate shape extending in the one direction Da. The O2 terminal 210 faces the O1 terminal 140 in the thickness direction DT. When the O2 terminal 210 is projected in the thickness direction DT, the projected O2 terminal 210 overlaps with the O1 terminal 140.

The third semiconductor element 211 faces the second semiconductor element 112 in the thickness direction DT. When the third semiconductor element 211 is projected in the thickness direction DT, the projected third semiconductor element 211 overlaps with the second semiconductor element 112. The third semiconductor element 211 corresponds to a third element, and includes a third transistor 271, a third bonding wire 281, and a third diode 291.

The third transistor 271 is, for example, a MOSFET using Si or SiC. The breakdown voltage of the third transistor 271 is 0.5 times or more and less than 1.0 times of the breakdown voltage of the first transistor 171. Further, the breakdown voltage of the third transistor 271 is 0.5 times or more and less than 1.0 times of the breakdown voltage of the second transistor 172. The third transistor 271 has a third drain electrode 2711, a third source electrode 2712, and a third gate electrode 2713, as shown in FIG. 1.

The third drain electrode 2711 corresponds to a fifth electrode. As shown in FIG. 5, the third drain electrode 2711 is connected to the fifth lead frame 221 via a solder or the like. Further, the fifth lead frame 221 is connected to the O2 terminal 210 via a solder or the like. Therefore, the third drain electrode 2711 is connected to the O2 terminal 210 via the fifth lead frame 221 and the like. In addition to the function of a connection component, the fifth lead frame 221 also functions as a heat spreader.

The third source electrode 2712 corresponds to a sixth electrode, and is connected to the sixth lead frame 222 via a solder, a copper spacer, or the like. In addition to the function of a connection component, the sixth lead frame 222 also functions as a heat spreader.

The third gate electrode 2713 is connected to the third lead terminal 231 via a pad, the third bonding wire 281, and the like. The third lead terminal 231 is connected to the drive circuit. The third gate electrode 2713 causes a current to flow between the third drain electrode 2711 and the third source electrode 2712 in accordance with the voltage applied to the third gate electrode 2713 from the drive circuit.

Returning to FIG. 1, the third diode 291 is, for example, a Zener diode. A cathode of the third diode 291 is connected to the third drain electrode 2711 and the fifth lead frame 221. An anode of the third diode 291 is connected to the third source electrode 2712 and the sixth lead frame 222. Thereby, the third diode 291 is connected in parallel with the third transistor 271.

As shown in FIG. 4, the fourth semiconductor element 212 faces the first semiconductor element 111 in the thickness direction DT. When the fourth semiconductor element 212 is projected in the thickness direction DT, the projected fourth semiconductor element 212 overlaps the first semiconductor element 111. The fourth semiconductor element 212 corresponds to a fourth element. The fourth semiconductor element 212 includes a fourth transistor 272, a fourth bonding wire 282, and a fourth diode 292.

The fourth transistor 272 is, for example, a MOSFET using Si or SiC. The breakdown voltage of the fourth transistor 272 is 0.5 times or more and less than 1.0 times of the breakdown voltage of the first transistor 171. The breakdown voltage of the fourth transistor 272 is 0.5 times or more and less than 1.0 times of the breakdown voltage of the second transistor 172. The fourth transistor 272 has a fourth drain electrode 2721, a fourth source electrode 2722, and a fourth gate electrode 2723, as shown in FIG. 1.

The fourth drain electrode 2721 corresponds to a seventh electrode. As shown in FIG. 4, the fourth drain electrode 2721 is connected to the seventh lead frame 223 via a solder or the like. In addition to the function of a connection component, the seventh lead frame 223 has a function of a heat spreader.

The fourth source electrode 2722 corresponds to an eighth electrode, and is connected to the eighth lead frame 224 via a solder, a copper spacer, or the like. As shown in FIG. 6, the eighth lead frame 224 is connected to the sixth lead frame 222 via a wiring layer or the like. Since the sixth lead frame 222 is connected to the third source electrode 2712, the fourth source electrode 2722 is connected to the third source electrode 2712 via the eighth lead frame 224, the sixth lead frame 222, and the like. In addition to the function of a connection component, the eighth lead frame 224 has a function of a heat spreader.

As shown in FIG. 4, the fourth gate electrode 2723 is connected to the fourth lead terminal 232 via a pad, the fourth bonding wire 282, and the like. The fourth lead terminal 232 is connected to the drive circuit. The fourth gate electrode 2723 causes a current to flow between the fourth drain electrode 2721 and the fourth source electrode 2722 in accordance with the voltage applied to the fourth gate electrode 2723 from the drive circuit.

Returning to FIG. 1, the fourth diode 292 is, for example, a Zener diode. A cathode of the fourth diode 292 is connected to the fourth drain electrode 2721 and the seventh lead frame 223. An anode of the fourth diode 292 is connected to the fourth source electrode 2722 and the eighth lead frame 224. Thereby, the fourth diode 292 is connected in parallel with the fourth transistor 272.

The N1 terminal 240 corresponds to a fifth terminal. As shown in FIG. 4, the N1 terminal 240 is connected to the seventh lead frame 223 via a solder or the like. Since the seventh lead frame 223 is connected to the fourth drain electrode 2721, the N1 terminal 240 is connected to the fourth drain electrode 2721 via the seventh lead frame 223. The N1 terminal 240 is made of a metal and has a plate shape extending in the one direction Da. The N1 terminal 240 faces the P terminal 110 in the thickness direction DT. When the N1 terminal 240 is projected in the thickness direction DT, the projected N1 terminal 240 overlaps the P terminal 110.

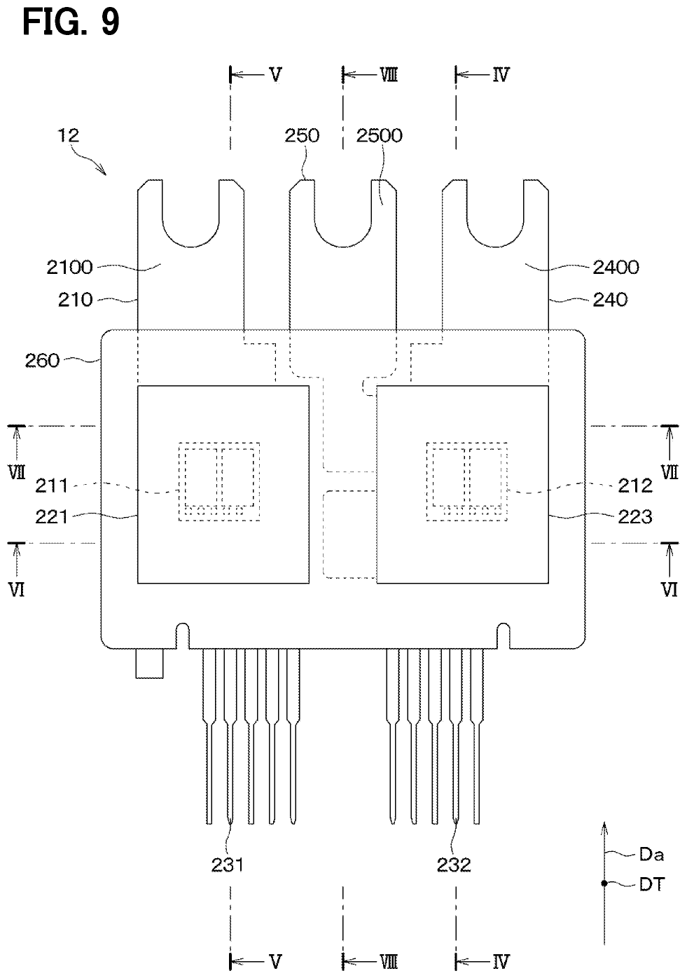

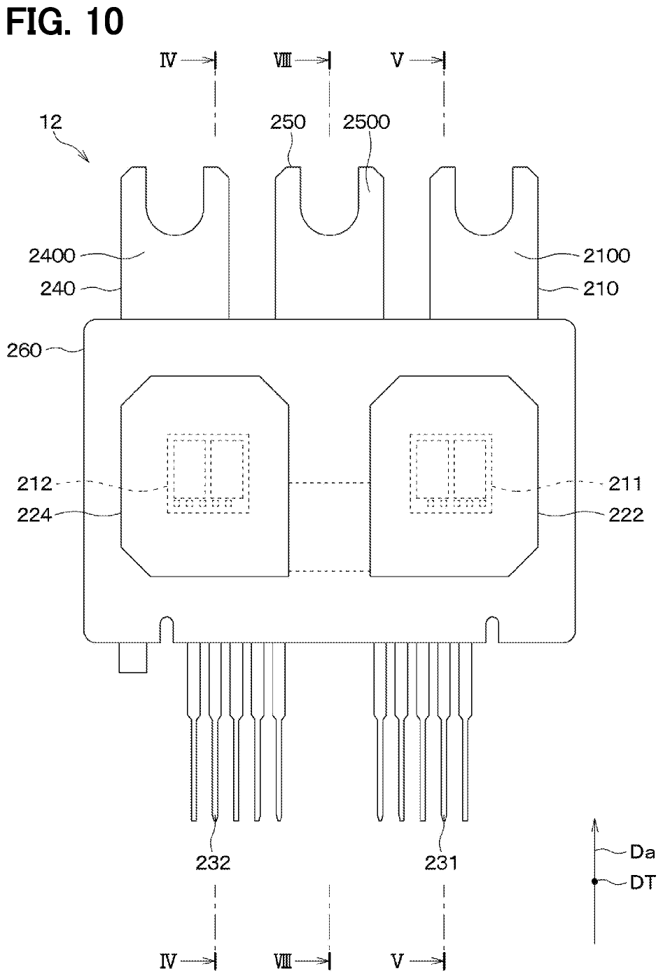

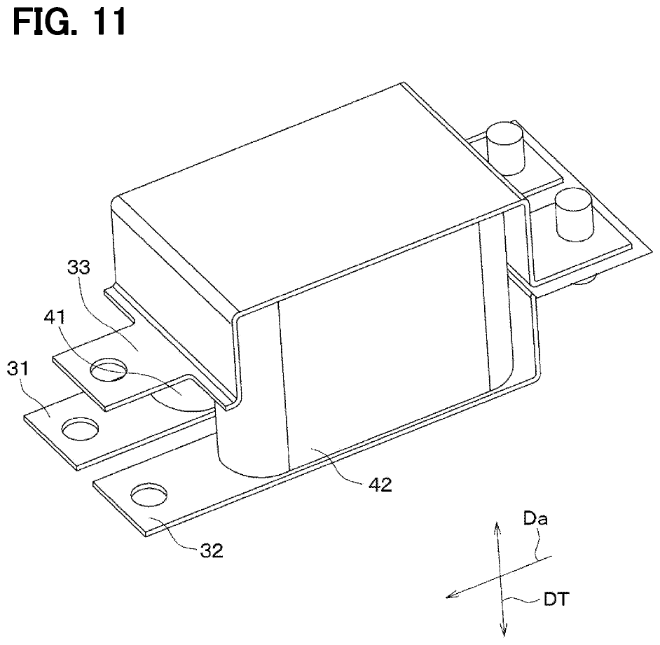

The N2 terminal 250 corresponds to a sixth terminal. The N2 terminal 250 is connected to the seventh lead frame 223 via a wiring layer, a solder, a copper spacer and the like, as shown in FIGS. 7 and 9. Since the seventh lead frame 223 is connected to the fourth drain electrode 2721, the N2 terminal 250 is connected to the fourth drain electrode 2721 via the seventh lead frame 223 and the like. The N2 terminal 250 is made of a metal and has a plate shape extending in the one direction Da. The N2 terminal 250 faces the N terminal 150 in the thickness direction DT. When the N2 terminal 250 is projected in the thickness direction DT, the projected N2 terminal 250 overlaps the N terminal 150. As shown in FIGS. 9 and 10, the N2 terminal 250 is arranged between the O2 terminal 210 and the N1 terminal 240 in the direction perpendicular to the one direction Da and the thickness direction Dt, and is spaced apart from the O2 terminal 210 and the N1 terminal 240.

The second sealing part 260 is made of a resin or the like. The second sealing part 260 covers the third semiconductor element 211 and the fourth semiconductor element 212. The second sealing part 260 covers the fifth lead frame 221 and the sixth lead frame 222 so that the fifth lead frame 221 and the sixth lead frame 222 are partly exposed from the second sealing part 260. The second sealing part 260 covers the seventh lead frame 223 and the eighth lead frame 224 so that the seventh lead frame 223 and the eighth lead frame 224 are partly exposed from the second sealing part 260. The second sealing part 260 covers a part of the third lead terminal 231 so that the third lead terminal 231 protrudes from the second sealing part 260. The second sealing part 260 covers a part of the fourth lead terminal 232 so that the fourth lead terminal 232 protrudes from the second sealing part 260. The second sealing part 260 covers a part of the O2 terminal 210 so that the O2 terminal 210 protrudes from the second sealing part 260. The second sealing part 260 covers a part of the N1 terminal 240 so that the N1 terminal 240 protrudes from the second sealing part 260. The second sealing part 260 covers a part of the N2 terminal 250 so that the N2 terminal 250 protrudes from the second sealing part 260.

Therefore, as shown in FIGS. 4, 5, and 8 to 10, the O2 terminal 210 has a fourth protrusion 2100 protruding from the second sealing part 260. The N1 terminal 240 has a fifth protrusion 2400 protruding from the second sealing part 260. The N2 terminal 250 has a sixth protrusion 2500 protruding from the second sealing part 260.

Here, as shown in FIGS. 4, 5, and 8, a plane passing through the center of the first sealing part 160 in the thickness direction DT and perpendicular to the thickness direction DT is defined as a first central plane So1. Further, a plane passing through the center of the second sealing part 260 in the thickness direction DT and perpendicular to the thickness direction DT is defined as a second central plane So2.

The first protrusion 1100 is located closer to the fifth protrusion 2400 than the first central plane So1. The second protrusion 1400 is located closer to the fourth protrusion 2100 than the first central plane So1. The third protrusion 1500 is located closer to the sixth protrusion 2500 than the first central plane So1. The fourth protrusion 2100 is located closer to the second protrusion 1400 than the second central plane So2. The fifth protrusion 2400 is located closer to the first protrusion 1100 than the second central plane So2. The sixth protrusion 2500 is located closer to the third protrusion 1500 than the second central plane So2.

The second module 12 has the same outer shape as the first module 11. For example, the outer shape of the first protrusion 1100 and the outer shape of the fifth protrusion 2400 are the same. The outer shape of the second protrusion 1400 and the outer shape of the fourth protrusion 2100 are the same. The outer shape of the third protrusion 1500 and the outer shape of the sixth protrusion 2500 are the same. The outer shapes of the first lead terminal 131 and the second lead terminal 132 protruding from the first sealing part 160 are the same as the outer shapes of the third lead terminal 231 and the fourth lead terminal 232 protruding from the second sealing part 260. The outer shape of the first sealing part 160 and the outer shape of the second sealing part 260 are the same. Note that here, “same” includes an error range in manufacturing.

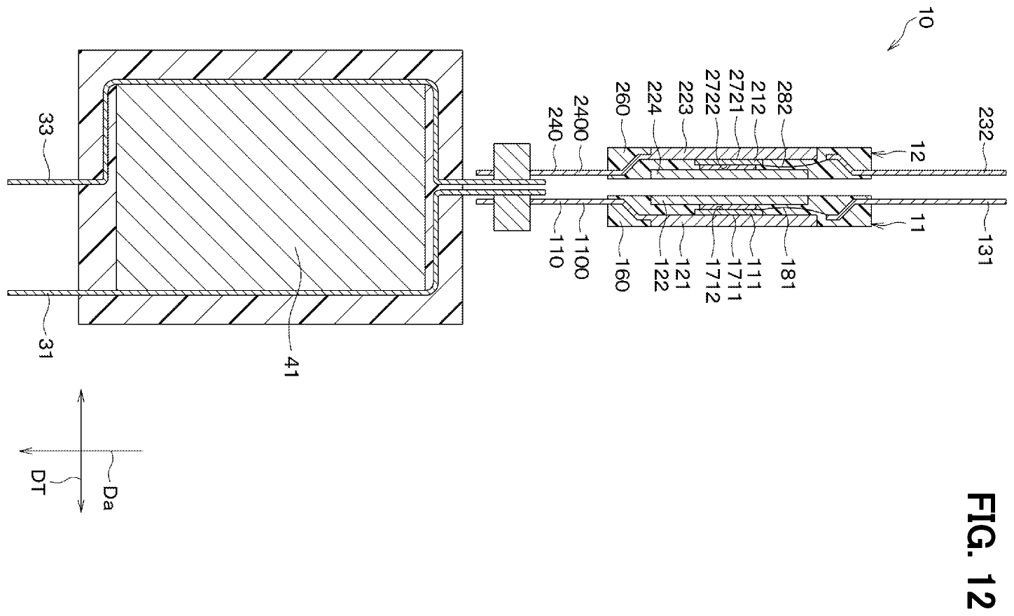

The first extension part 31 is connected to the P terminal 110 via a bolt or the like, as shown in FIGS. 11 and 12. Further, the first extension part 31 is made of a metal and has a plate shape extending from the P terminal 110 in the one direction Da. The first extension part 31 has a bent at a part. Further, the first extension part 31 is connected to one end of a power supply (not shown).

The second extension part 32 is connected to the N terminal 150 via a bolt or the like. Further, the second extension part 32 is made of a metal and has a plate shape extending from the N terminal 150 in the one direction Da. The second extension part 32 has a bent at a part. Further, the second extension part 32 is connected to the other end of the power supply.

The third extension part 33 is connected to the N1 terminal 240 and the N2 terminal 250 via bolts or the like. The third extension part 33 is made of a metal and has a plate shape extending from the N1 terminal 240 and the N2 terminal 250 in the one direction Da. The third extension part 33 has a bent at a part.

The first capacitor 41 is formed by metallicon or the like. The first capacitor 41 is interposed between the first extension part 31 and the third extension part 33. The first capacitor 41 is connected to the first extension part 31 and the third extension part 33.

The second capacitor 42 is formed by metallicon or the like. The second capacitor 42 is interposed between the second extension part 32 and the third extension part 33. The second capacitor 42 is connected to the second extension part 32 and the third extension part 33. A part of the first extension part 31, a part of the second extension part 32, a part of the third extension part 33, the first capacitor 41, and the second capacitor 42 are covered with resin or the like.

The semiconductor module 10 of the first embodiment is configured as described above. Next, an operation of the semiconductor module 10 will be explained.

A control device (not shown) controls the voltage applied from the drive circuit to the first gate electrode 1713 via the first lead terminal 131 and the like, and the voltage applied from the drive circuit to the second gate electrode 1723 via the second lead terminal 132 and the like. Thereby, the first semiconductor element 111 and the second semiconductor element 112 are controlled to be turned on and off. The control device also controls the voltage applied from the drive circuit to the third gate electrode 2713 via the third lead terminal 231 and the like, and the voltage applied from the drive circuit to the fourth gate electrode 2723 via the fourth lead terminal 232 and the like. Thereby, the third semiconductor element 211 and the fourth semiconductor element 212 are controlled to turned on and off. Accordingly, the current according to the on and off controls of the first semiconductor element 111, the second semiconductor element 112, the third semiconductor element 211, and the fourth semiconductor element 212 is output from the O1 terminal 140 to the motor. In this way, the motor is controlled.

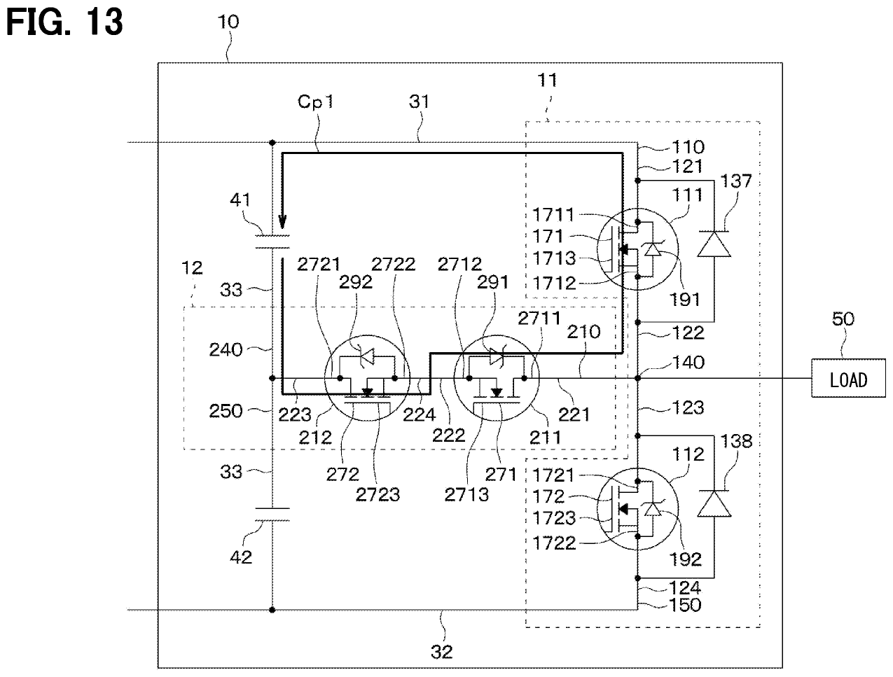

As shown in FIGS. 13 to 16, a first commutation path Cp1, a second commutation path Cp2, a third commutation path Cp3, and the fourth commutation path Cp4 are formed according to the on and off controls of the first semiconductor element 111, the second semiconductor element 112, the third semiconductor element 211, and the fourth semiconductor element 212. Note that the commutation path here refers to the path of a displacement current dl/dt caused when the current path is switched by turning on and off the first semiconductor element 111, the second semiconductor element 112, the third semiconductor element 211, and the fourth semiconductor element 212.

In the first commutation path Cp1, as shown in FIG. 13, the displacement current dl/dt passes through the first capacitor 41, the third extension part 33, the N1 terminal 240, the seventh lead frame 223 and the fourth transistor 272, and then passes through the eighth lead frame 224. The displacement current dl/dt that has passed through the eighth lead frame 224 passes through the sixth lead frame 222, the third diode 291, the fifth lead frame 221, and the O2 terminal 210, and then passes through the O1 terminal 140. The displacement current dl/dt that has passed through the O1 terminal 140 passes through the third lead frame 123, the second lead frame 122, the first transistor 171, the first lead frame 121, the P terminal 110, and the first extension part 31, and then passes through the first capacitor 41.

In the first commutation path Cp1, as shown in FIG. 17, the displacement current dl/dt passes through the third lead frame 123 via the O1 terminal 140. The displacement current dl/dt that has passed through the third lead frame 123 passes through the second lead frame 122, the first source electrode 1712, and the first drain electrode 1711, and then passes through the first lead frame 121. The displacement current dl/dt that has passed through the first lead frame 121 passes through the P terminal 110. In this case, the direction of the current path in the P terminal 110 is along the one direction Da. On the contrary, the direction of the current path in the O1 terminal 140 is opposite to the one direction Da.

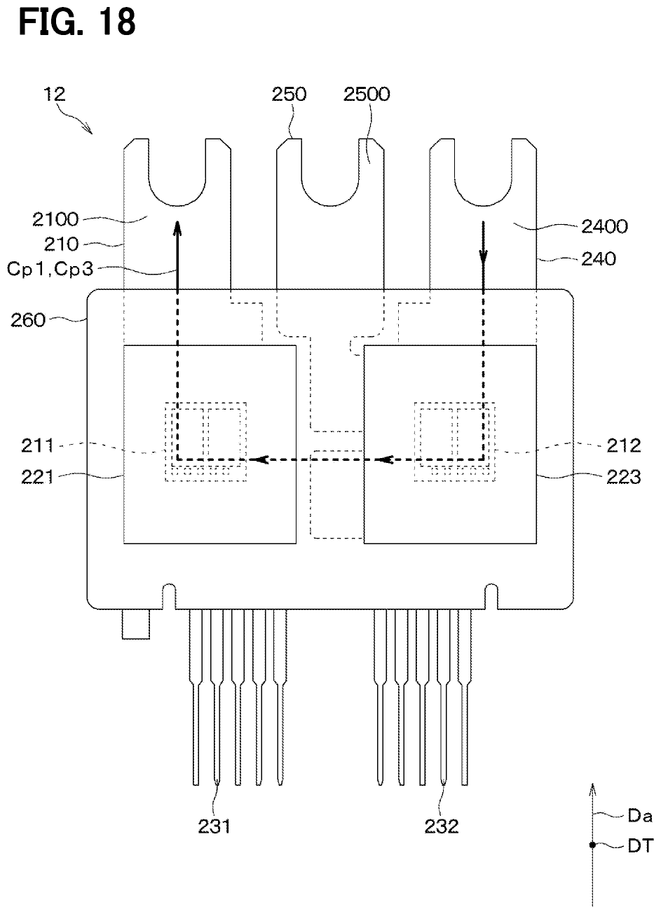

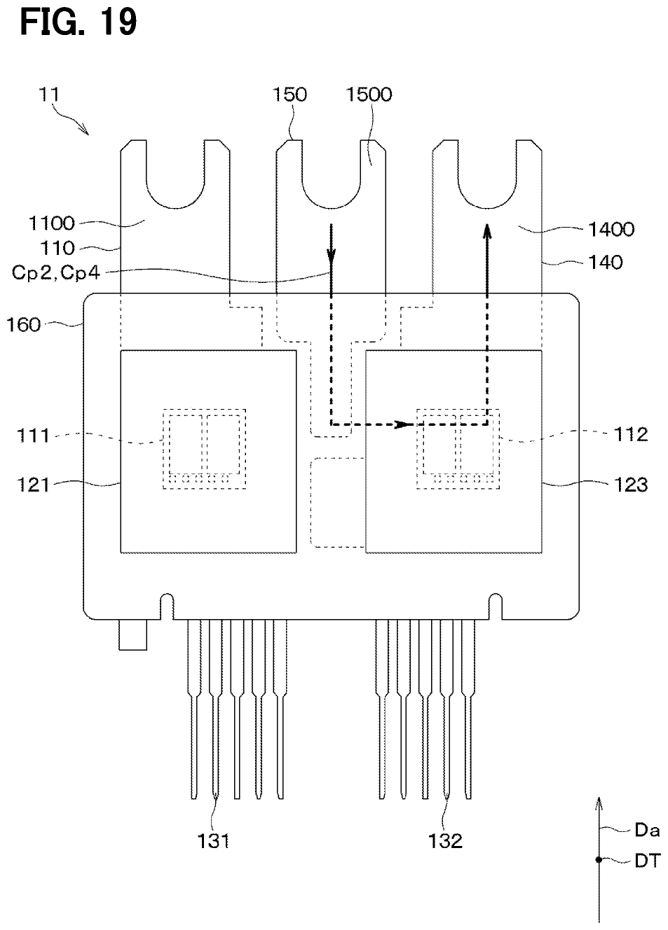

In the first commutation path Cp1, as shown in FIG. 18, the displacement current dl/dt passes through the seventh lead frame 223 via the N1 terminal 240. The displacement current dl/dt that has passed through the seventh lead frame 223 passes through the fourth drain electrode 2721, the fourth source electrode 2722, the eighth lead frame 224, the sixth lead frame 222, and the third diode 291, and then passes through the fifth lead frame 221. The displacement current dl/dt that has passed through the fifth lead frame 221 passes through the O2 terminal 210. In this case, the direction of the current path in the N1 terminal 240 is opposite to the one direction Da. On the contrary, the direction of the current path in the O2 terminal 210 is along the one direction Da.

Therefore, the direction of the current path in the P terminal 110, which faces the N1 terminal 240 in the thickness direction DT, is opposite to the direction of the current path in the N1 terminal 240. Further, the direction of the current path in the O1 terminal 140, which faces the O2 terminal 210 in the thickness direction DT, is opposite to the direction of the current path in the O2 terminal 210. As such, the direction of the current path in the first module 11 is opposite to the direction of the current path in the second module 12.

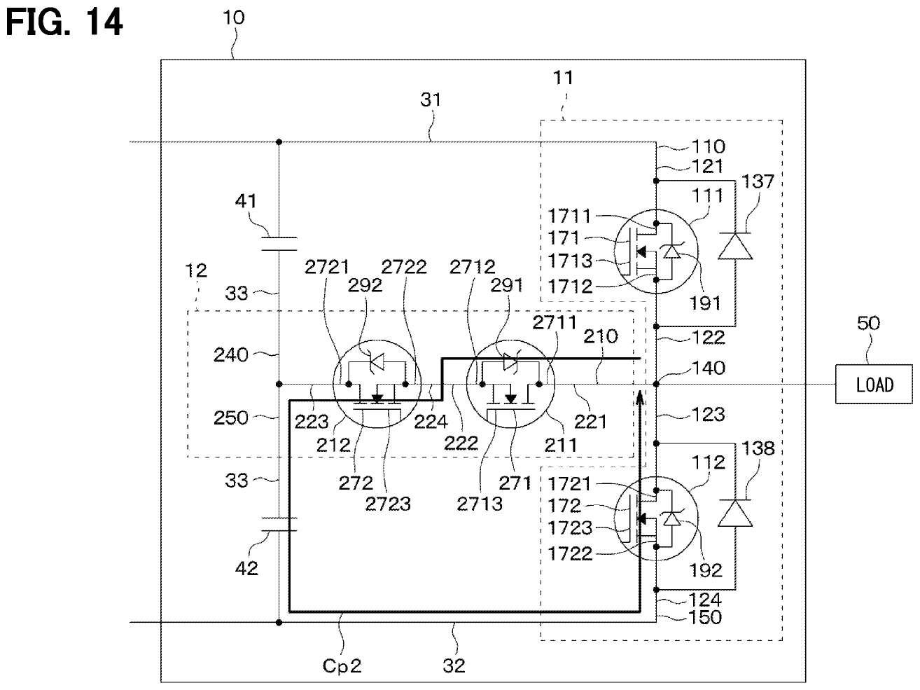

In the second commutation path Cp2, as shown in FIG. 14, the displacement current dl/dt passes through the O2 terminal 210, the fifth lead frame 221, the third diode 291, and the sixth lead frame 222, and then passes through the eighth lead frame 224. The displacement current dl/dt that has passed through the eighth lead frame 224 passes the fourth transistor 272, the seventh lead frame 223, the N2 terminal 250, the third extension part 33, the second capacitor 42, and the second extension part 32, and then passes through the N terminal 150. The displacement current dl/dt that has passed through the N terminal 150 passes through the fourth lead frame 124, the second transistor 172, the third lead frame 123, and the O1 terminal 140, and then passes through the O2 terminal 210.

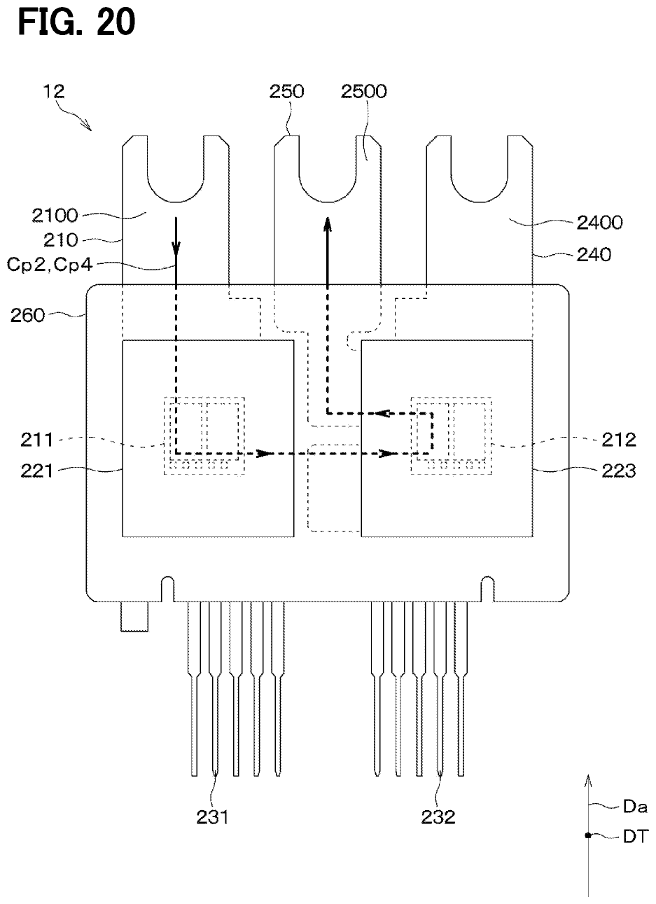

In the second commutation path Cp2, as shown in FIG. 19, the displacement current dl/dt passes the N terminal 150, the fourth lead frame 124, the second source electrode 1722 and the second rain electrode 1721, and then passes through the third lead frame 123. The displacement current dl/dt that has passed through the third lead frame 123 passes through the O1 terminal 140. In this case, the direction of the current path in the N terminal 150 is opposite to the one direction Da. On the contrary, the direction of the current path in the O1 terminal 140 is along the one direction Da.

In the second commutation path Cp2, as shown in FIG. 20, the displacement current dl/dt passes through the fifth lead frame 221 via the O2 terminal 210. The displacement current dl/dt that has passed through the fifth lead frame 221 passes the third diode 291, the sixth lead frame 222, the eighth lead frame 224, the fourth source electrode 2722, and the fourth drain electrode 2721, and then passes through the seventh lead frame 223. The displacement current dl/dt that has passed through the seventh lead frame 223 passes through the N2 terminal 250. In this case, the direction of the current path in the N2 terminal 250 is along the one direction Da. On the contrary, the direction of the current path in the O2 terminal 210 is opposite to the one direction Da.

Therefore, the direction of the current path in the N terminal 150, which faces the N2 terminal 250 in the thickness direction DT, is opposite to the direction of the current path in the N2 terminal 250. Further, the direction of the current path in the O1 terminal 140, which faces the O2 terminal 210 in the thickness direction DT, is opposite to the direction of the current path in the O2 terminal 210. As such, the direction of the current path in the first module 11 is opposite to the direction of the current path in the second module 12.

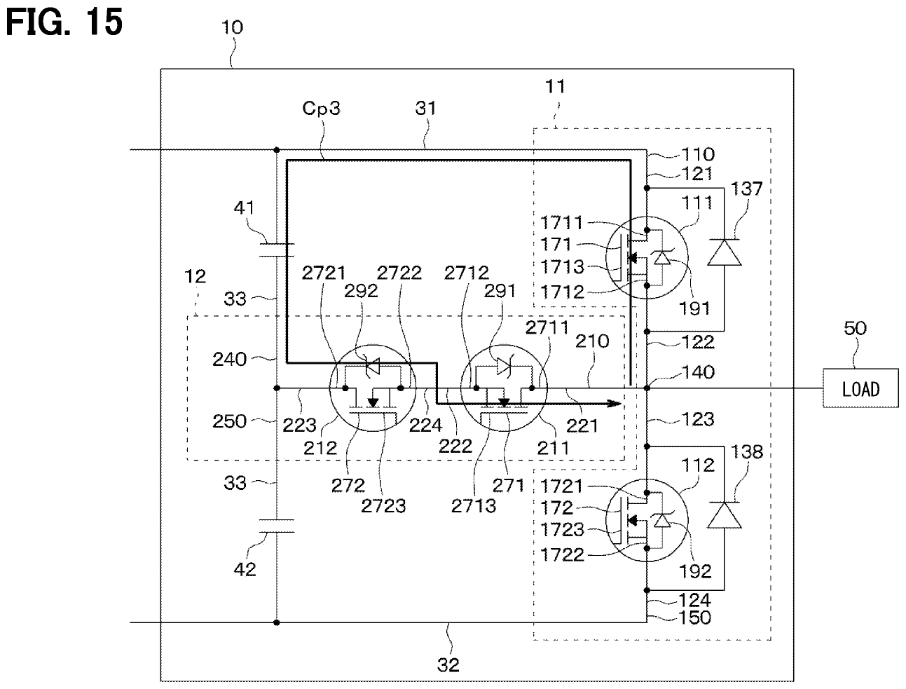

In the third commutation path Cp3, as shown in FIG. 15, the displacement current dl/dt passes through the O1 terminal 140, the third lead frame 123, the second lead frame 122, the first transistor 171, and the first lead frame 121, and then passes through the P terminal 110. The displacement current dl/dt that has passed through the P terminal 110 passes through the first capacitor 41 via the first extension part 31. The displacement current dl/dt that has passed through the first capacitor 41 passes through the third extension part 33, the N1 terminal 240, the seventh lead frame 223, and the fourth diode 292, and then passes through the eighth lead frame 224. The displacement current dl/dt that has passed through the eighth lead frame 224 passes through the sixth lead frame 222, the third transistor 271, the fifth lead frame 221, and the O2 terminal 210, and then passes through the O1 terminal 140.

In the third commutation path Cp3, as shown in FIG. 17, the displacement current dl/dt passes through the third lead frame 123 via the O1 terminal 140. The displacement current dl/dt that has passed through the third lead frame 123 passes through the second lead frame 122, the first source electrode 1712, and the first drain electrode 1711, and then passes through the first lead frame 121. The displacement current dl/dt that has passed through the first lead frame 121 passes through the P terminal 110. In this case, the direction of the current path in the P terminal 110 is along the one direction Da. On the contrary, the direction of the current path in the O1 terminal 140 is opposite to the one direction Da.

Further, in the third commutation path Cp3, as shown in FIG. 18, the displacement current dl/dt passes through the seventh lead frame 223 via the N1 terminal 240. The displacement current dl/dt that has passed through the seventh lead frame 223 passes through the fourth diode 292, the eighth lead frame 224, the sixth lead frame 222, the third source electrode 2712, and the third drain electrode 2711, and then passes through the fifth lead frame 221. The displacement current dl/dt that has passed through the fifth lead frame 221 passes through the O2 terminal 210. In this case, the direction of the current path at the N1 terminal 240 is opposite to the one direction Da. On the contrary, the direction of the current path in the O2 terminal 210 is along the one direction Da.

Therefore, the direction of the current path in the P terminal 110, which faces the N1 terminal 240 in the thickness direction DT, is opposite to the direction of the current path in the N1 terminal 240. Further, the direction of the current path in the O1 terminal 140, which faces the O2 terminal 210 in the thickness direction DT, is opposite to the direction of the current path in the O2 terminal 210. As such, the direction of the current path in the first module 11 is opposite to the direction of the current path in the second module 12.

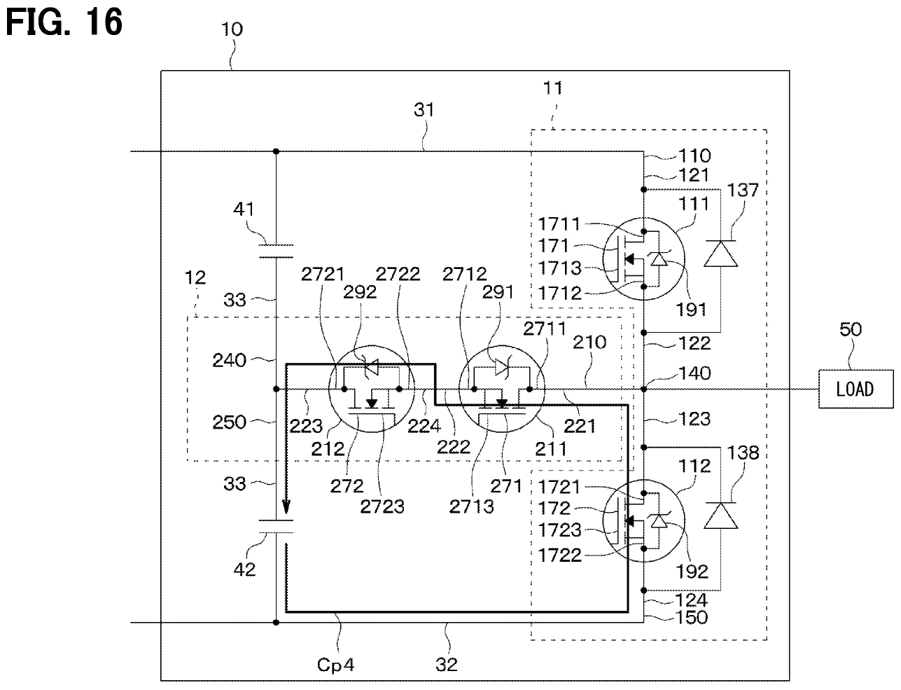

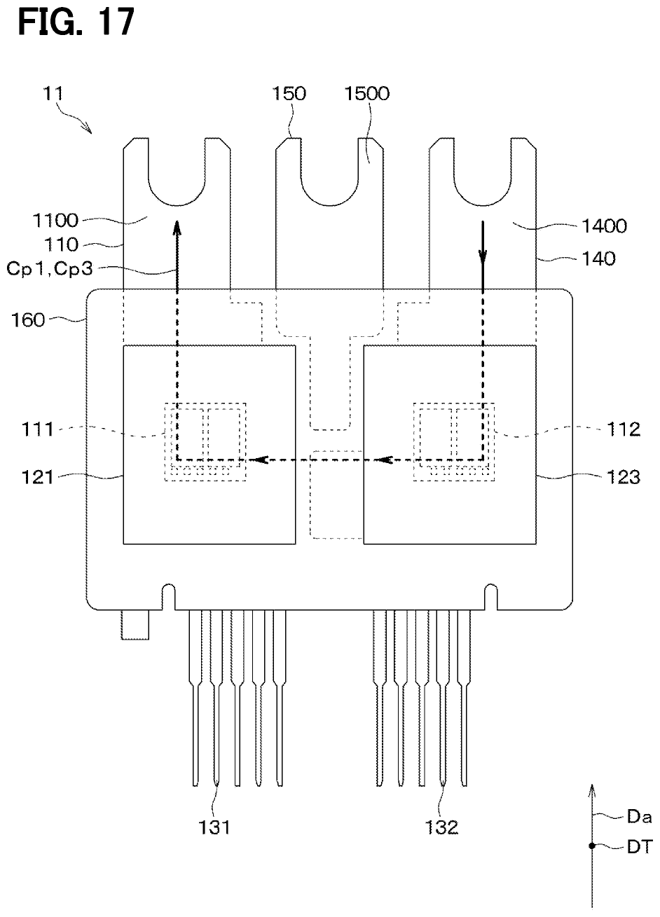

In the fourth commutation path Cp4, as shown in FIG. 16, the displacement current dl/dt passes through the N terminal 150 via the second capacitor 42 and the second extension part 32. The displacement current dl/dt that passed through the N terminal 150 passes through the fourth lead frame 124, the second transistor 172, the third lead frame 123, and the O1 terminal 140, and then passes through the O2 terminal 210. The displacement current dl/dt that has passed through the O2 terminal 210 passes through the fifth lead frame 221, the third transistor 271, and the sixth lead frame 222, and then passes through the eighth lead frame 224. The displacement current dl/dt that has passed through the eighth lead frame 224 passes through the fourth diode 292, the seventh lead frame 223, the N2 terminal 250, and the third extension part 33, and then passes through the second capacitor 42.

In the fourth commutation path Cp4, as shown in FIG. 19, the displacement current dl/dt passes through the fourth lead frame 124, the second source electrode 1722 and the second drain electrode 1721 from the N terminal 150, and then passes through the third lead frame 123. The displacement current dl/dt that has passed through the third lead frame 123 passes through the O1 terminal 140. In this case, the direction of the current path in the O1 terminal 140 is along the one direction Da. On the contrary, the direction of the current path in the N terminal 150 is opposite to the one direction Da.

In the fourth commutation path Cp4, as shown in FIG. 20, the displacement current dl/dt passes through the O2 terminal 210 and then passes through the fifth lead frame 221. The displacement current dl/dt that has passed through the fifth lead frame 221 passes through the third drain electrode 2711, the third source electrode 2712, the sixth lead frame 222, the eighth lead frame 224, and the fourth diode 292, and then passes through the lead frame 223. The displacement current dl/dt that has passed through the seventh lead frame 223 passes through the N2 terminal 250. In this case, the direction of the current path in the O2 terminal 210 is opposite to the one direction Da. On the contrary, the direction of the current path in the N2 terminal 250 is along the one direction Da.

Therefore, the direction of the current path in the N terminal 150, which faces the N2 terminal 250 in the thickness direction DT, is opposite to the direction of the current path in the N2 terminal 250. The direction of the current path in the O1 terminal 140, which faces the O2 terminal 210 in the thickness direction DT, is opposite to the direction of the current path in the O2 terminal 210. As such, the direction of the current path in the first module 11 is opposite to the direction of the current path in the second module 12.

The semiconductor module 10 operates as described above. Next, suppression of an increase in inductance in the semiconductor module 10 will be explained.

In the semiconductor module 10, the first module 11 and the second module 12 are connected to each other by connecting the O1 terminal 140 and the O2 terminal 210 to each other. The first module 11 faces the second module 12 in the thickness direction DT. Further, the direction of the current path in the first module 11 is opposite to the direction of the current path in the second module 12. For example, the P terminal 110 faces the N1 terminal 240 in the thickness direction DT. The direction of the current path in the P terminal 110 is opposite to the direction of the current path in the N1 terminal 240. The O1 terminal 140 faces the O2 terminal 210 in the thickness direction DT. The direction of the current path in the O1 terminal 140 is opposite to the direction of the current path in the O2 terminal 210. The N terminal 150 faces the N2 terminal 250 in the thickness direction DT. The direction of the current path in the N terminal 150 is opposite to the direction of the current path in the N2 terminal 250.

As a result, there is a portion where the directions of the magnetic fields due to the currents flowing through the first module 11 and the second module 12 are different from each other. For this reason, the first module 11 and the second module 12 cancel the magnetic fields each other. Therefore, an increase in inductance in the first module 11 and the second module 12 is suppressed. As such, an increase in inductance of the semiconductor module 10 is suppressed. In addition, since the increase in the inductance of the semiconductor module 10 is suppressed, an increase in surge voltage generated in the semiconductor module 10 is suppressed. Therefore, failure or damage of the first semiconductor element 111, the second semiconductor element 112, the third semiconductor element 211, and the fourth semiconductor element 212 is suppressed.

Moreover, the semiconductor module 10 of the first embodiment also achieves the effects described below.

(1-1) As shown in FIG. 4, the first protrusion 1100 is located closer to the fifth protrusion 2400 than the first central plane So1. The fifth protrusion 2400 is located closer to the first protrusion 1100 than the second central plane So2.

With this configuration, the first protrusion 1100 and the fifth protrusion 2400 can be arranged close to each other. Therefore, the first protrusion 1100 and the fifth protrusion 2400 mutually, easily cancel the magnetic field thereof. As such, an increase in inductance between the first protrusion 1100 and the fifth protrusion 2400 is suppressed.

As shown in FIG. 5, the second protrusion 1400 is located closer to the fourth protrusion 2100 than the first central plane So1. The fourth protrusion 2100 is located closer to the second protrusion 1400 than the second central plane So2.

With this configuration, the second protrusion 1400 and the fourth protrusion 2100 can be arranged close to each other. Therefore, the second protrusion 1400 and the fourth protrusion 2100 mutually, easily cancel the magnetic fields thereof. As such, an increase in inductance between the second protrusion 1400 and the fourth protrusion 2100 is suppressed.

Further, as shown in FIG. 8, the third protrusion 1500 is located closer to the sixth protrusion 2500 than the first central plane So1. The sixth protrusion 2500 is located closer to the third protrusion 1500 than the second central plane So2.

With this configuration, the third protrusion 1500 and the sixth protrusion 2500 ae arranged close to each other. Therefore, the third protrusion 1500 and the sixth protrusion 2500 mutually, easily cancel the magnetic fields thereof. As such, an increase in inductance between the third protrusion 1500 and the sixth protrusion 2500 is suppressed. Accordingly, an increase in the inductance of the semiconductor module 10 is suppressed.

(1-2) The outer shape of the first module 11 and the outer shape of the second module 12 are the same. For example, the outer shape of the first protrusion 1100 and the outer shape of the fifth protrusion 2400 are the same. The outer shape of the second protrusion 1400 and the outer shape of the fourth protrusion 2100 are the same. The outer shape of the third protrusion 1500 and the outer shape of the sixth protrusion 2500 are the same. The outer shapes of the first lead terminal 131 and second lead terminal 132 protruding from the first sealing part 160 and the outer shapes of the third lead terminal 231 and fourth lead terminal 232 protruding from the second sealing part 260 are the same. The outer shape of the first sealing part 160 and the outer shape of the second sealing part 260 are the same.

In this case, for example, the first module 11 and the second module 12 can be molded using the same mold. The semiconductor module 10 can be manufactured more easily than in the case where the outer shape of the first module 11 and the outer shape of the second module 12 are different.

(1-3) The voltages applied to the third semiconductor element 211 and the fourth semiconductor element 212 are lower than the voltages applied to the first semiconductor element 111 and the second semiconductor element 112. However, the time period in which the current flows through the third semiconductor element 211 and the fourth semiconductor element 212 is longer than the time period in which the current flows through the first semiconductor element 111 and the second semiconductor element 112. Therefore, the third semiconductor element 211 and the fourth semiconductor element 212 generate heat relatively easily.

On the other hand, in the semiconductor module 10, the breakdown voltage of the third transistor 271 in the third semiconductor element 211 is 0.5 times or more and less than 1.0 times of the breakdown voltage of the first transistor 171 in the first semiconductor element 111. Further, the breakdown voltage of the third transistor 271 is 0.5 times or more and less than 1.0 times of the breakdown voltage of the second transistor 172 in the second semiconductor element 112. Furthermore, the withstand voltage of the fourth transistor 272 in the fourth semiconductor element 212 is 0.5 times or more and less than 1.0 times of the withstand voltage of the first transistor 171. The breakdown voltage of the fourth transistor 272 is 0.5 times or more and less than 1.0 times of the breakdown voltage of the second transistor 172.

As a result, the on-resistances of the third semiconductor element 211 and the fourth semiconductor element 212 are smaller than the on-resistances of the first semiconductor element 111 and the second semiconductor element 112. For this reason, the amount of heat generated by the third semiconductor element 211 and the amount of heat generated by the fourth semiconductor element 212 are relatively small. Therefore, failure or damage of the third semiconductor element 211 and the fourth semiconductor element 212 is suppressed.

(1-4) As shown in FIGS. 11 and 12, the semiconductor module 10 includes the first extension part 31, the second extension part 32, the third extension part 33, the first capacitor 41, and the second capacitor 42. The first extension part 31 is connected to the P terminal 110 and extended in the one direction Da. The second extension part 32 is connected to the N terminal 150 and extended in the one direction Da. The third extension part 33 is connected to the N1 terminal 240 and the N2 terminal 250, and extended in the one direction Da. The first capacitor 41 is interposed between the first extension part 31 and the third extension part 33, and is connected to the first extension part 31 and the third extension part 33. The second capacitor 42 is interposed between the second extension part 32 and the third extension part 33, and is connected to the second extension part 32 and the third extension part 33.

As a result, the direction of the current path between the P terminal 110 and the first capacitor 41 is opposite to the direction of the current path between the N1 terminal 240 and the first capacitor 41. For this reason, there is a portion where the direction of the magnetic field due to the current flowing between the P terminal 110 and the first capacitor 41 is opposite to the direction of the magnetic field due to the current flowing between the N1 terminal 240 and the first capacitor 41. Therefore, the magnetic fields between the P terminal 110 and the first capacitor 41 and between the N1 terminal 240 and the first capacitor 41 are cancelled out each other. As such, an increase in inductance between the P terminal 110 and the first capacitor 41 and between the N1 terminal 240 and the first capacitor 41 is suppressed.

The direction of the current path between the N terminal 150 and the second capacitor 42 is opposite to the direction of the current path between the N2 terminal 250 and the second capacitor 42. For this reason, there is a portion where the direction of the magnetic field due to the current flowing between the N terminal 150 and the second capacitor 42 is opposite to the direction of the magnetic field due to the current flowing between the N2 terminal 250 and the second capacitor 42. Therefore, the magnetic fields between the N terminal 150 and the second capacitor 42 and between the N2 terminal 250 and the second capacitor 42 are cancelled out each other. As such, an increase in inductance between N terminal 150 and second capacitor 42 and between N2 terminal 250 and second capacitor 42 is suppressed. Accordingly, the increase in inductance of the semiconductor module 10 is suppressed.

### Second Embodiment

In a second embodiment, the shapes of the first lead frame 121, the second lead frame 122, the third lead frame 123, and the fourth lead frame 124 are different from those of the first embodiment. Further, the configurations of the fifth lead frame 221, the sixth lead frame 222, the seventh lead frame 223, and the eighth lead frame 224 are different from those of the first embodiment. The other configurations are similar to those of the first embodiment.

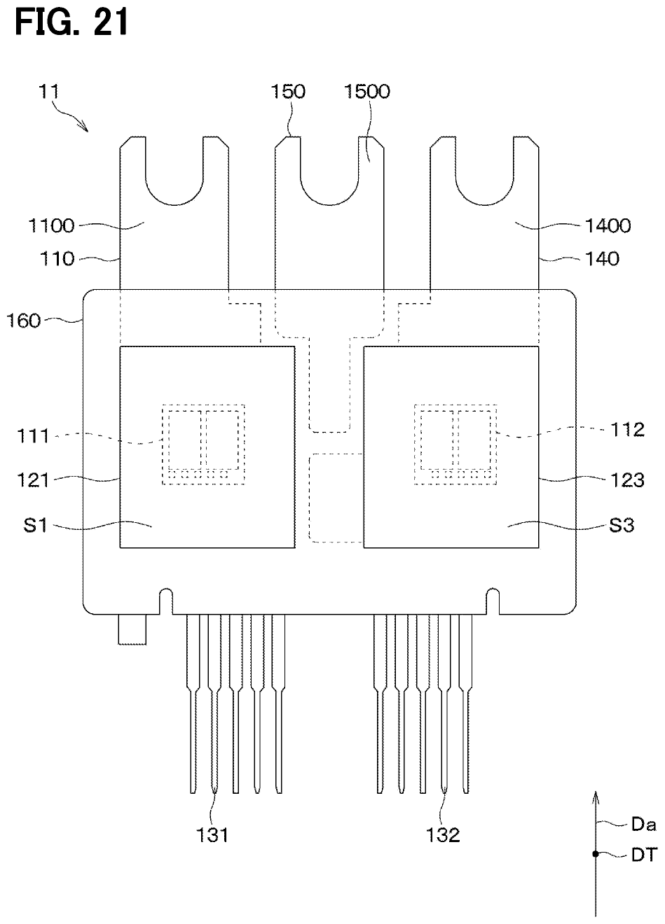

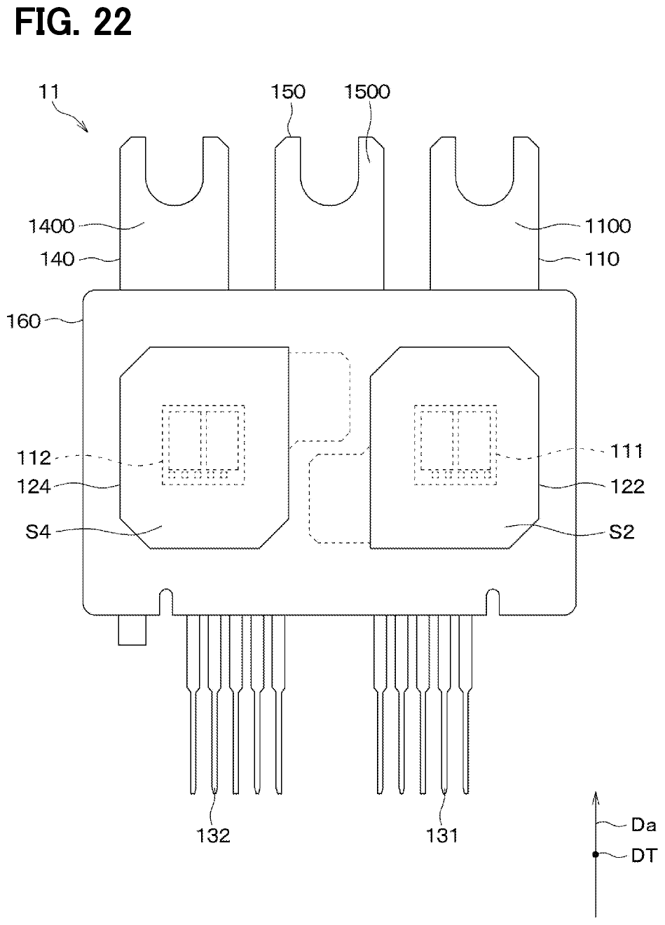

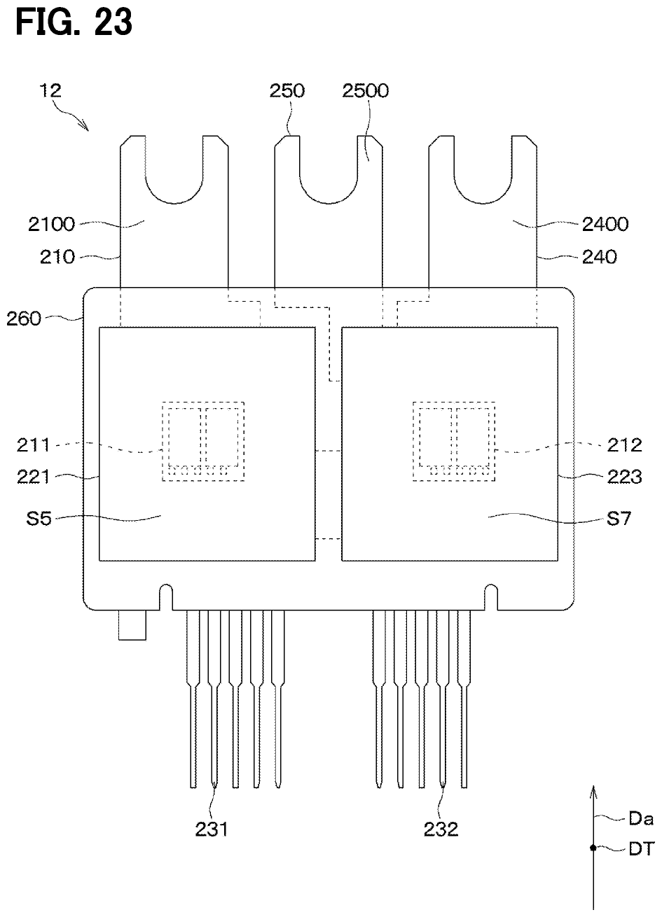

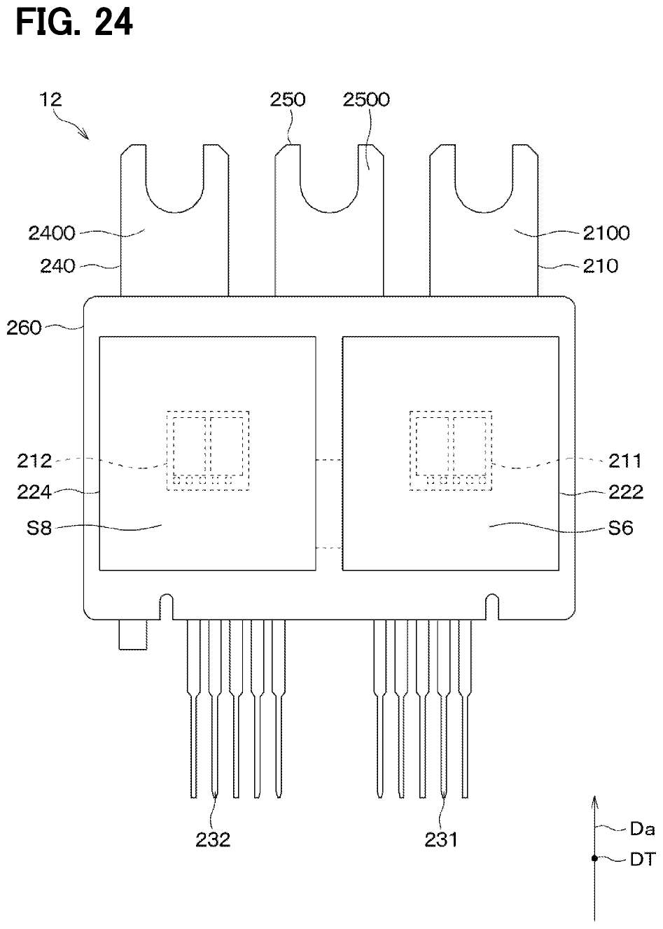

As shown in FIG. 21, the area of the first lead frame 121 exposed from the first sealing part 160 is defined as a first area S1. The area of the third lead frame 123 exposed from the first sealing part 160 is referred to as a third area S3. As shown in FIG. 22, the area of the second lead frame 122 exposed from the first sealing part 160 is referred to as a second area S2. The area of the fourth lead frame 124 exposed from the first sealing part 160 is referred to as a fourth area S4. As shown in FIG. 23, the area of the fifth lead frame 221 exposed from the second sealing part 260 is referred to as a fifth area S5. The area of the seventh lead frame 223 exposed from the second sealing part 260 is referred to as a seventh area S7. As shown in FIG. 24, the area of the sixth lead frame 222 exposed from the second sealing part 260 is referred to as a sixth area S6. The area of the eighth lead frame 224 exposed from the second sealing part 260 is referred to as an eighth area S8.

The fifth area S5 is larger than the first area S1, the second area S2, the third area S3, and the fourth area S4. That is, relationships of S5>S1, S5>S2, S5>S3, and S5>S4 are satisfied. The sixth area S6 is larger than the first area S1, the second area S2, the third area S3, and the fourth area S4. That is, relationships of S6>S1, S6 >S2, S6>S3, and S6>S4 are satisfied. The seventh area S7 is larger than the first area S1, the second area S2, the third area S3, and the fourth area S4. That is, relationships of S7>S1, S7>S2, S7>S3, and S7>S4 are satisfied. The eighth area S8 is larger than the first area S1, the second area S2, the third area S3, and the fourth area S4. That is, relationships of S8>S1, S8>S2, S8>S3, and S8>S4 are satisfied.

The semiconductor module 10 of the second embodiment is configured as described above. The second embodiment achieves the similar effects to the first embodiment. In addition, the second embodiment achieves the following effects.

(2) As described above, the third semiconductor element 211 and the fourth semiconductor element 212 generate heat relatively easily.

In the semiconductor module 10 of the second embodiment, any of the fifth area S5, the sixth area S6, the seventh area S7, and the eighth area S8 is larger than any of the first area S1, the second area S2, the third area S3 and the fourth area S4.

As a result, the fifth lead frame 221, the sixth lead frame 222, the seventh lead frame 223, and the eighth lead frame 224 can dissipate heat more easily, as compared to the case where the first to eighth areas S1 to S8 are the same. Therefore, the temperature rise of the third semiconductor element 211 and the fourth semiconductor element 212 is suppressed. As such, failure or damage of the third semiconductor element 211 and the fourth semiconductor element 212 is suppressed.

### Other Embodiments

The present disclosure is not limited to the embodiments described above, and can be appropriately modified in various ways. In addition, in each of the above-described embodiments, it is understood that all the elements constituting the embodiments are not necessarily essential except for a case where it is explicitly stated that the elements are particularly essential and a case where the elements are considered to be obviously essential in principle.

In each of the embodiments described above, the first transistor 171, the second transistor 172, the third transistor 271, and the fourth transistor 272 are MOSFETs, as an example. However, the present disclosure is not limited thereto. The first transistor 171, the second transistor 172, the third transistor 271, and the fourth transistor 272 may be insulated gate bipolar transistors (IGBTs) or the like.

In each of the embodiments described above, the first diode 191, the second diode 192, the third diode 291, and the fourth diode 292 are Zener diodes, as an example. However, the present disclosure is not limited thereto. The first diode 191, the second diode 192, the third diode 291, and the fourth diode 292 may be rectifying diodes or the like.

In each of the embodiments described above, the sixth lead frame 222 and the eighth lead frame 224 are separate members. On the other hand, the sixth lead frame 222 and the eighth lead frame 224 may be integrated.

In each of the embodiments described above, the semiconductor module 10 is used in a three-level inverter. However, the use of the semiconductor module 10 is not limited to such an example. The semiconductor module 10 may be used in a two-level inverter.

While only the selected exemplary embodiments and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiments and examples according to the present disclosure is provided for illustration only, and not for the purpose of limiting the disclosure as defined by the appended claims and their equivalents.

What is claimed is:

1. A semiconductor module comprising:
a first module; and
a second module, wherein
the first module includes:
a first terminal extending in a first direction;
a first element that includes a first electrode connected to the first terminal, a second electrode, a first gate electrode that causes a current to flow between the first electrode and the second electrode in response to a voltage application, and a first diode connected to the first electrode and the second electrode;
a second element that includes a third electrode connected to the second electrode, a fourth electrode, a second gate electrode that causes a current to flow between the third electrode and the fourth electrode in response to a voltage application, and a second diode connected to the third electrode and the fourth electrode;
a second terminal that is connected to the third electrode, extended in the first direction, and is to be connected to a load;
a third terminal that is connected to the fourth electrode and extended in the first direction,
the second module includes:
a fourth terminal that extended in the first direction and connected to the second terminal so as to connect the first module and the second module to each other;
a third element that includes a fifth electrode connected to the fourth terminal, a sixth terminal, a third gate electrode that causes a current to flow between the fifth electrode and the sixth electrode in response to a voltage application, and a third diode connected to the fifth electrode and the sixth electrode;
a fourth element that includes a seventh electrode, an eighth electrode connected to the sixth electrode, a fourth gate that causes a current to flow between the seventh electrode and the eighth electrode in response to a voltage application, and a fourth diode connected to the seventh electrode and the eighth electrode;
a fifth terminal that is connected to the seventh electrode and extended in the first direction; and
a sixth terminal that is connected to the seventh electrode and extended in the first direction,
the first module faces the second module in a thickness direction of the first module, and
a direction of a current path in the first module is opposite to a direction of a current path in the second module.

2. The semiconductor module according to claim 1, wherein
the first terminal faces the fifth terminal in the thickness direction,
a direction of a current path in the first terminal is opposite to a direction of a current path in the fifth terminal,
the second terminal faces the fourth terminal in the thickness direction,
a direction of a current path in the second terminal is opposite to a direction of a current path in the fourth terminal,
the third terminal faces the sixth terminal in the thickness direction, and
a direction of a current path in the third terminal is opposite to a direction of a current path in the sixth terminal.

3. The semiconductor module according to claim 2, wherein
the first module includes a first sealing part that covers the first element, the second element, the first terminal, the second terminal, and the third terminal,
the second module includes a second sealing part that covers the third element, the fourth element, the fourth terminal, the fifth terminal, and the sixth terminal,
the first terminal has a first protrusion protruding from the first sealing part,
the second terminal has a second protrusion protruding from the first sealing part,
the third terminal has a third protrusion protruding from the first sealing part,
the fourth terminal has a fourth protrusion protruding from the second sealing part,
the fifth terminal has a fifth protrusion protruding from the second sealing part,
the sixth terminal has a sixth protrusion protruding from the second sealing part,
a plane that is perpendicular to the thickness direction and passes through a center of the first sealing part in the thickness direction is referred to as a first central plane,
a plane that is perpendicular to the thickness direction and passes through a center of the second sealing part in the thickness direction is referred to as a second central plane,
the first protrusion is located closer to the fifth protrusion than the first central plane in the thickness direction,
the second protrusion is located closer to the fourth protrusion than the first central plane in the thickness direction,
the third protrusion is located closer to the sixth protrusion than the first central plane in the thickness direction,
the fourth protrusion is located closer to the second protrusion than the second central plane in the thickness direction,
the fifth protrusion is located closer to the first protrusion than the second central plane in the thickness direction, and
the sixth protrusion is located closer to the third protrusion than the second central plane in the thickness direction.

4. The semiconductor module according to claim 1, wherein
the first module includes:
a first lead frame connected to the first electrode;
a second lead frame connected to the second electrode;
a third lead frame connected to the third electrode and the second lead frame;
a fourth lead frame connected to the fourth electrode; and
a first sealing part covering the first element, the second element, the first terminal, the second terminal, the third terminal, the first lead frame, the second lead frame, the third lead frame, and the fourth lead frame,
the second module includes:
a fifth lead frame connected to the fifth electrode and the fourth terminal;
a sixth lead frame connected to the sixth electrode;
a seventh lead frame connected to the seventh electrode;
an eighth lead frame connected to the eighth electrode and the sixth lead frame;
a second sealing part covering the third element, the fourth element, the fourth terminal, the fifth terminal, the sixth terminal, the fifth lead frame, the sixth lead frame, the seventh lead frame, and the eighth lead frame,
at least a portion of each of the first lead frame, the second lead frame, the third lead frame, and the fourth lead frame is exposed from the first sealing part,
at least a portion of the fifth lead frame, the sixth lead frame, the seventh lead frame, and the eighth lead frame is exposed from the second sealing part, and
an area of any of the fifth lead frame, the sixth lead frame, the seventh lead frame, and the eighth lead frame exposed from the second sealing part is larger than an area of any of the first lead frame, the second lead frame, the third lead frame, and the fourth lead frame exposed from the first sealing part.

5. The semiconductor module according to claim 1, wherein
the first module and the second module have a same outer shape.

6. The semiconductor module according to claim 1, wherein
a breakdown voltage of the third element and the fourth element is 0.5 times or more and less than 1.0 times of a breakdown voltage of the first element, and is 0.5 times or more and less than 1.0 times of a breakdown voltage of the second element.

7. The semiconductor module according to claim 1, wherein
the semiconductor module further includes:
a first extension part connected to the first terminal and extended in the first direction;
a second extension part connected to the third terminal and extended in the first direction;
a third extension part connected to the fifth terminal and the sixth terminal and extended in the first direction;
a first capacitor interposed between the first extension part and the third extension part and connected to the first extension part and the third extension part; and
a second capacitor disposed between the second extension part and the third extension part and connected to the second extension part and the third extension part.
